(19) United States
(12) Patent Application Publication
(10) Pub. No.: US 2008/0261402 A1
(43) Pub. Date: Oct. 23, 2008

(54) METHOD OF REMOVING INSULATING LAYER ON SUBSTRATE

(75) Inventors: Chan Lu, Tainan County (TW); Teng-Chun Tsai, Hsinchu (TW); Chih-Yueh Li, Taipei City (TW); Kai-Gin Yang, Tainan County (TW); Chien-Chung Huang, Taichung Hsien (TW); Chia-Hsi Chen, Kaohsiung City (TW); Tzu-Hui Wu, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/736,006

(22) Filed: Apr. 17, 2007

(51) Int. Cl. H01L 21/302

(52) U.S. Cl. 438/693; 451/285; 257/E21.214

(57) ABSTRACT

A method of removing an insulating layer on a substrate is described, including a first CMP process and a second CMP process performed in sequence, wherein the polishing slurry used in the first CMP process and that used in the second CMP process have substantially the same pH value that exceeds 7.0. A cleaning step is conducted between the first and the second CMP processes to remove a specific substance which would otherwise cause undesired particles to form in the second CMP process.

### BACKGROUND OF THE INVENTION

1. Field of Invention

The present invention relates to a semiconductor process, and more particularly to a method of removing an insulating layer on a substrate as well as to a corresponding chemical mechanical polishing (CMP) process.

2. Description of Related Art

For the linewidth of semiconductor process is continuously reduced, ultra-large scale integrated circuit (ULSI) chips with high speed, more functions, high integration degree, low power consumption and low cost can be produced in mass. However, since the linewidth reduction needs thinner photoresist and progressively tighter depth of focus, the requirement to flatness of the substrate surface gets higher. Currently, global planarization of a wafer surface depends on the chemical mechanical polishing (CMP) technology, which has a unique property of anisotropic removal and can be applied to, except global planarization of wafer surfaces, formation of damascene structures of vertical/horizontal interconnects, front-end shallow trench isolation (STI) processes, fabrication of advanced devices, planarization processes of micro-electromechanical systems (MEMS) and fabrication of flat-plane display apparatuses.

A CMP process typically utilizes a mechanical polishing effect in company with suitable slurry capable of causing hydrolysis to planarize a surface. In a conventional CMP process, the surface to be polished of a wafer is pressed onto a rotary polishing pad with slurry containing an abrasive and an assist chemical supplied between them. When the protrudent portions of the wafer surface contact with the polishing pad, the contact portions is subject to hydrolysis due to the assist chemical and is mechanically polished by the abrasive simultaneously. With the combination of chemical reaction and mechanical polishing, a planar surface can be obtained.

The fixed-abrasive CMP (FACMP) technique has also been proposed, using a polishing pad embedded with abrasive particles therein. The abrasive particles will be released during the polishing process for the mechanical polishing.

A non-fixed-abrasive CMP process has a high polishing rate, but easily causes dishing on the polished object. Although a fixed-abrasive CMP process can prevent dishing, it has a low polishing rate and is therefore not utilized alone.

A method has been reported using non-fixed-abrasive CMP and fixed-abrasive CMP in combination to remove an insulating layer on a wafer, which firstly performs a non-fixed-abrasive CMP using high-selectivity (HSS) slurry “SiLECT 6000” to polish the insulating layer in a high rate, and then performs a SWR521 fixed-abrasive CMP process for fine polishing. The method can prevent dishing and improve the removal rate. However, the variation of polishing rate of a HSS slurry is non-linear, and the process window is quite narrow.

Another method is to firstly perform a non-fixed-abrasive CMP using silica-type slurry to polish the insulating layer in a high rate, and then performs a fixed-abrasive CMP process with a ceria abrasive-embedded pad. Though the method increases the process window, it easily causes serious microscratch for the reasons below. During the fixed-abrasive CMP process, the residual silica abrasive from the non-fixed-abrasive CMP process can be hydrolyzed at the surfaces to form —SiOH that dissociates to —SiO⁻ and H⁺, and the CeO₂ abrasive can also be hydrolyzed at the surfaces to form —CeOH that dissociates to —Ce⁺ and OH⁻. Because —Ce⁺ and —SiO⁻ readily cause a Lewis acid-base reaction, large solid CeₓSiO_{y} particles are formed and easily scratch the wafer surface during the CMP process. The reaction mechanism is illustrated as follows.

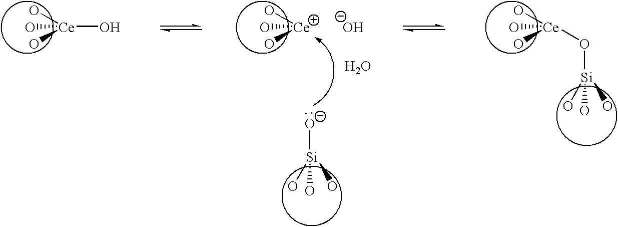

### SUMMARY OF THE INVENTION

Accordingly, this invention provides a method of removing an insulating layer on a substrate, which can increase the process window and reduce the microscratch on the wafer surface.

This invention also provides a CMP process capable of increasing the process window and reducing the microscratch on the wafer surface.

The method of removing an insulating layer on a substrate of this invention includes a first CMP process and a second CMP process conducted in sequence, wherein the polishing slurry used in the first CMP process and that used in the second CMP process have substantially the same pH value that exceeds 7.0. A cleaning step is conducted between the first and the second CMP processes to remove a specific substance which otherwise causes undesired particles in the second CMP process.

The above cleaning step may be conducted on a polishing platen that is the same as or different from the polishing platen used in the first CMP process.

It is feasible that the first CMP process includes a non-fixed-abrasive CMP process and the second CMP process includes a fixed-abrasive CMP process. In certain embodiments, the specific substance to be removed is a first abrasive used in the first CMP process, wherein the first abrasive can interact with a second abrasive used in the second CMP process to form the undesired particles. In some cases, the first abrasive includes silicon oxide, the second abrasive includes cerium oxide and the undesired particles include CeₓSiO_{y}.

In an embodiment wherein the specific substance capable of causing undesired particles is particles of the first abrasive, the above cleaning step may include flushing the substrate with deionized (DI) water and simultaneously buffing the substrate. The cleaning step may be conducted on a polishing platen being the same as or different from that used in the first CMP process. The cleaning step may be conducted on a polishing platen equipped with a buff pad that is different from the polishing platen used in the first CMP process.

In another embodiment wherein the specific substance is the first abrasive, the cleaning step includes treating the substrate with a chemical solution such that the surface of the insulating layer and the first abrasive remaining thereon have charges of the same sign, and simultaneously buffing the substrate. The cleaning step may be conducted on a polishing platen different from that used in the first CMP process, wherein the polishing platen may be equipped with a buff pad. In addition, the above chemical solution may include ammonia or a solution containing ammonia.

In still another embodiment wherein the specific substance is the first abrasive, the cleaning step at least includes using a chemical solution to remove a portion of the insulating layer and the first abrasive remaining thereon. In a case, the cleaning step is conducted in a chemical solution tank. In another case, the cleaning step further includes simultaneously buffing the substrate, possibly on a polishing platen different from that used in the first CMP process. Such a polishing platen may be equipped with a buff pad. The above chemical solution may include an acid solution, which may include dilute hydrofluoric acid or a solution containing hydrofluoric acid.

In an embodiment wherein the first CMP process includes a non-fixed-abrasive CMP process and the second CMP process includes a fixed-abrasive CMP process, the non-fixed-abrasive CMP process, the fixed-abrasive CMP process and the cleaning step may be conducted in the same CMP machine.

It is also possible that the first and second CMP processes each independently include a non-fixed-abrasive CMP process or a fixed-abrasive CMP process.

In addition, the above insulating layer may be an insulating Layer for forming the insulator of a shallow trench isolation (STI) structure, or be a dielectric layer.

Moreover, the method of removing an insulating layer on a substrate of this invention may further include a step of flushing the substrate with deionized water (DI) and simultaneously buffing the substrate after the second CMP process is performed, so as to remove the residues on the substrate.

The CMP process for polishing a target layer on a substrate of this invention is described as follows. A first CMP step is conducted to the target layer on a first polishing platen, a cleaning step is conducted to the same on a second platen, and then a second CMP step is conducted to the same layer on a third platen. Particularly, the slurry used in the first polishing platen and that used in the third polishing platen have substantially the same pH value that exceeds 7.0 The cleaning step removes a specific substance which would otherwise cause undesired particles in the second CMP process.

In an embodiment, the second polishing platen is equipped with a buff pad, while the cleaning step may include flushing the substrate with deionized water and buffing the substrate simultaneously, or include treating the substrate with a chemical solution and buffing the target layer simultaneously. The chemical solution may include ammonia or a solution containing ammonia, or alternatively include an acid solution which may include dilute hydrofluoric acid or a solution containing hydrofluoric acid.

In some embodiments, the first and the second CMP steps each independently include a non-fixed-abrasive CMP step or a fixed-abrasive one. In certain cases, the first CMP step uses a first abrasive including silicon oxide, the second CMP step uses a second abrasive including cerium oxide, and the undesired particles include CeₓSiO_{y}.

By utilizing the method of removing an insulating layer on a substrate of this invention, the process window can be increased and the microscratch on the substrate surface can be reduced.

In order to make the aforementioned and other objects, features and advantages of the present invention comprehensible, a preferred embodiment accompanied with figures is described in detail below.

### BRIEF DESCRIPTION OF THE DRAWINGS

FIG. 1 is a flow chart of a method of removing an insulating layer on a substrate according to an embodiment of this invention.

FIGS. 2A-2F depict, in a cross-sectional view, a process flow of an STI process according to an embodiment of this invention.

FIGS. 3A-3D depict, in a cross-sectional view, a process flow of the planarization of a dielectric layer of a device according to an embodiment of this invention.

### DESCRIPTION OF EMBODIMENTS

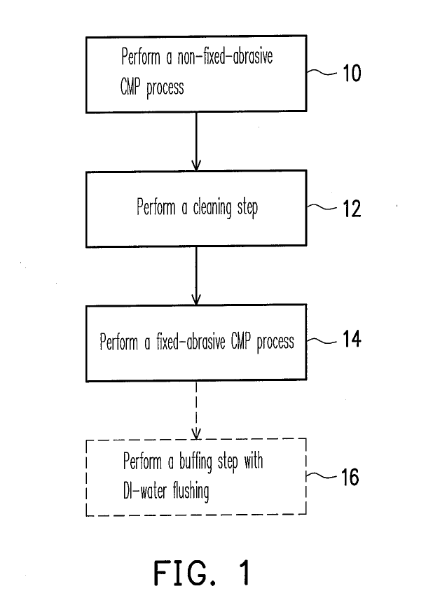

FIG. 1 is a flow chart of a method of removing an insulating layer on a substrate according to an embodiment of this invention.

Referring to FIG. 1, in the method of the embodiment, a non-fixed-abrasive CMP process is conducted first (step 10) to rapidly remove a portion of the insulating layer. In a case, the slurry used in the non-fixed-abrasive CMP process is silica-type slurry, such as the SS-25 slurry produced by Cabot Corporation that has a pH value over 7.0. It is noted that the silica-based abrasive can be hydrolyzed at the surface to form —SiOH that dissociates to H⁺ and —SiO⁻, which readily causes a Lewis acid-base reaction with the —Ce⁺ at the surface of the ceria-based abrasive to cause CeₓSiO_{y} particles. Hence, when the step 10 uses a silica-based abrasive and a CMP process using a ceria-based abrasive is done directly after the step 10 as in the prior art, the silica-based abrasive remaining on the insulating layer causes undesired particles of CeₓSiO_{y} in the next CMP to easily scratch the wafer surface. The CMP machine for removing the insulating layer may have 3 polishing platens, wherein the step 10 is conducted on the first one.

In next step 12, a cleaning step is conducted, possibly in the same CMP machine used in the step 10, to remove the remaining abrasive capable of causing undesired particles. In a case where the step 10 uses a silica-based abrasive, the substance to be removed is the silica-based abrasive remaining on the insulating layer surface.

In an embodiment, the cleaning step includes flushing the substrate with high-pressure deionized (DI) water and simultaneously buffing the substrate to mechanically assist removing the abrasive remaining on the insulating layer surface. The cleaning step may be conducted in-situ on the same polishing platen used in the step 10 or be conducted on another platen. As the cleaning step is conducted on another platen, a CMP machine including at least a platen equipped with a buff pad can be used.

In another embodiment, the cleaning step utilizes a chemical solution to change the zeta potential at the surface of the insulating layer such that the surface and the remaining abrasive thereon carry charges of the same sign and repel each other, and simultaneously buffs the substrate to mechanically assist removing the abrasive. When the insulating layer includes silicon oxide and the step 10 uses a silica-based abrasive, the chemical solution may be a base solution, which makes the surface of the insulating layer and the silica-based abrasive both carry negative charges and repel each other. The base solution used in the cleaning step may be ammonia, or a solution containing ammonia, such as a solution containing ammonia and H₂O₂ that is possibly an RCA solution containing 20 wt % or less of ammonia. Such a cleaning step is conducted on a polishing platen different from that used in the step 10, which may be equipped with a buff pad. In an embodiment where the CMP machine for removing the insulating layer includes three polishing platens, the cleaning step is conducted on the second one.

In another embodiment, the cleaning step uses a chemical solution to remove a part of the insulating layer and the remaining abrasive thereon. When the insulating layer includes silicon oxide, the chemical solution may be an acid-containing solution that etches silicon oxide, such as dilute hydrofluoric acid or a solution containing the same in 0.02-1 wt %. In some cases, the cleaning step is implemented by dipping the substrate into a chemical solution tank containing the chemical solution. In other cases, the cleaning step not only uses the chemical solution to remove a part of the insulating layer but also buffs the substrate simultaneously to mechanically assist removing the abrasive particles. Such a cleaning step is conducted on a polishing platen different from that used in step 10, wherein the polishing platen may be equipped with a buff pad. In an embodiment where the CMP machine for removing the insulating layer includes three polishing platens, the above cleaning step is conducted on the second one.

In next step 14, a fixed-abrasive CMP process is conducted, possibly in the same CMP machine used in the above steps, to fine polish the insulating layer. The slurry used in this CMP process has a pH value that exceeds 7.0 and is substantially the same as the pH value of the polishing slurry used in the step 10. The fixed-abrasive CMP process uses a polishing pad embedded with an abrasive therein, wherein the abrasive may be a ceria-based abrasive, or another abrasive that would cause undesired particles to form if co-existing with the abrasive (e.g., silica-based abrasive) used in the step 10. For the step 12 had removed the remaining abrasive from the first CMP process, no CeₓSiO_{y} particles are formed to scratch the wafer surface during the step 14. The step 14 is conducted on a polishing platen different from that for conducting the cleaning step. In an embodiment where the CMP machine for removing the insulating layer includes three polishing platens, the above step 14 is conducted on the third one.

After the step 14, a step 16 may be added according to the real requirements and the platen number of the CMP machine. The step 16 is a buffing step with DI-water flushing for removing the remaining abrasive of the polishing slurry and contaminations on the insulating layer. The step 16 is conducted on a polishing platen different from that used in the step 14, wherein the polishing platen may be equipped with a buff pad.

As mentioned above, the insulating layer suitably to be polished with the method of this invention may include silicon oxide. The method according to the embodiment mentioned above can be applied to the formation of an STI structure.

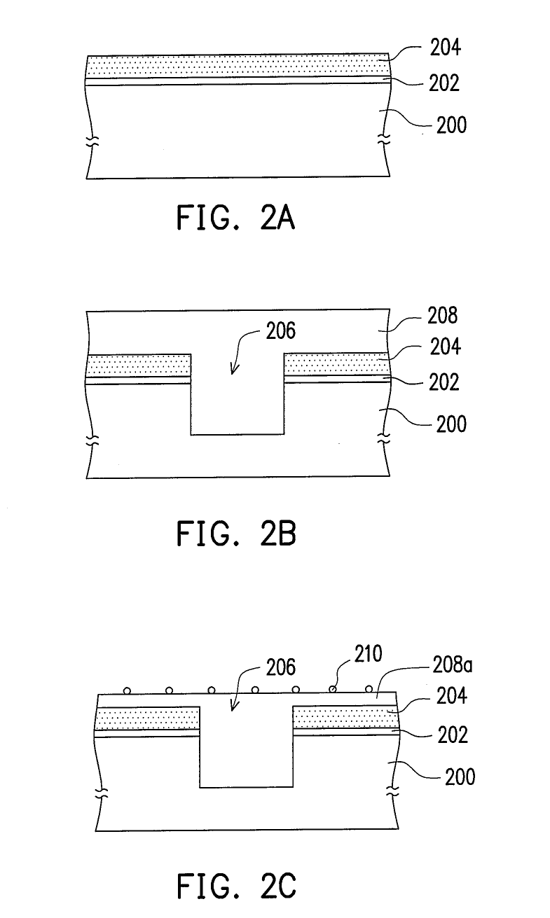

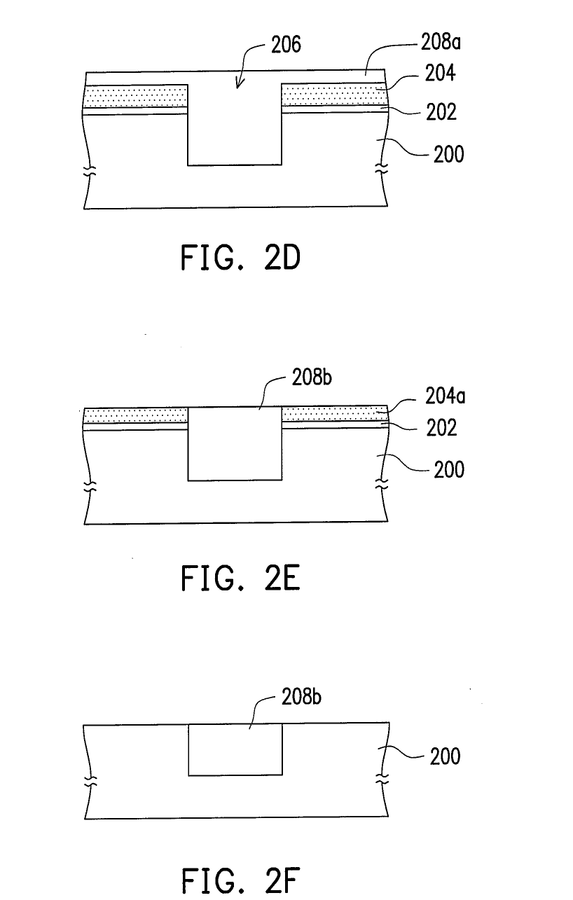

FIGS. 2A-2F depict, in a cross-sectional view, a process flow of an STI process according to an embodiment of this invention.

Referring to FIG. 2A, a pad oxide layer 202 and a mask layer 204 are formed on a substrate 200. The pad oxide layer 202 may be formed through thermal oxidation. The mask layer 204 may include silicon nitride, and may be formed with CVD.

Referring to FIG. 2B, the mask layer 204 and pad oxide layer 202 are patterned, and then the substrate 200 is etched to form a trench 206 therein. An insulating layer 208 is deposited over the substrate 200, possibly including silicon oxide and possibly formed through PECVD, in a thickness of about 6000 angstroms, for example.

Referring to FIG. 2C, a non-fixed-abrasive CMP process is conducted (step 10 in FIG. 1) to the insulating layer 208 until the thickness of the remaining insulating layer 208a on the mask layer 204 is reduced to 150-500 angstroms. The polishing slurry used in this CMP process may be silica-type slurry, such as the SS25 slurry produced by the Cabot Corporation that has a pH value exceeding 7.0. After the non-fixed-abrasive CMP, there are some abrasive 210 remaining on the surface of the insulating layer 208a. In an embodiment, the CMP machine used in the STI process includes three polishing platens, wherein the above non-fixed-abrasive CMP is conducted on the first one.

Referring to FIG. 2D, a cleaning step is performed (as step 12 in FIG. 1) to remove the remaining abrasive on the insulating layer 208a which would otherwise cause undesired particles in next CMP process. In a case where the CMP machine used in the STI process has 3 polishing platens, the cleaning step is conducted on the second one. If the step 10 uses a silica-based abrasive, the substance to be removed with the cleaning step is the silica-based abrasive 210 on the insulating layer 208a. The cleaning step may include flushing of high-pressure DI water and simultaneous buffing, or include application of a chemical solution (with simultaneous buffing).

The chemical solution used may be a base solution, which can change the zeta potential at the surface of the insulating layer 208a such that the surface of the insulating layer 208a and the remaining abrasive 210 thereon carry charges of the same sign and repel each other. The base solution may be ammonia, or a solution containing ammonia, such as a solution containing ammonia and H₂O₂ that is possibly an RCA solution produced by the RCA Corporation and containing 20 wt % or less of ammonia.

The chemical solution used may alternatively be an acid-containing solution, which can remove a portion of the insulating layer 208 and the abrasive particles 210 remaining thereon. The acid-containing solution may be dilute hydrofluoric acid or a solution containing hydrofluoric acid in a concentration of 0.02-1 wt %.

Referring to FIG. 2E, a fixed-abrasive CMP process is conducted (as step 14 in FIG. 1) to the insulating layer 208a until the mask 204 is exposed, wherein the slurry used in this CMP process has a pH value that exceeds 7.0 and is substantially the same as that of the slurry used in the previous non-fixed-abrasive CMP. In an embodiment where the CMP machine used in the STI process includes three polishing platens, the fixed-abrasive CMP process is conducted on the third one. The fixed-abrasive CMP process may use a polishing pad embedded with a ceria-based abrasive therein. The thickness loss of the mask 204 may be controlled to ˜50 angstroms, and the remaining mask layer and insulating layer are labeled with 204a and 208b, respectively. In the prior art where the two CMP processes are conducted without a cleaning step between them, the —Ce⁺ at the surfaces of ceria-based abrasive readily reacts with the —SiO⁻ at the surfaces of silica-based abrasive to cause CeₓSiO_{y} particles scratching the wafer surface. In this embodiment, the microscratch caused by CeₓSiO_{y} particles is effectively reduced for the step 12 had removed the remains of the silica-based abrasive used previously.

Referring to FIG. 2F, the mask layer 204 and pad oxide layer 202 are removed, which may be done through isotropic etching, for example, wet etching.

Moreover, a buffing step with DI water flushing may be further conducted (as step 16 in FIG. 1) as required, so as to remove the residues on the insulating layer 208b after the second CMP process.

In addition, as confirmed with some experiments, the microscratch formed on a wafer surface can be reduced by 86% with the method of the above embodiment.

The method according to the embodiment of this invention not only is applicable to formation of an STI structure, but also can be applied to planarize a dielectric layer.

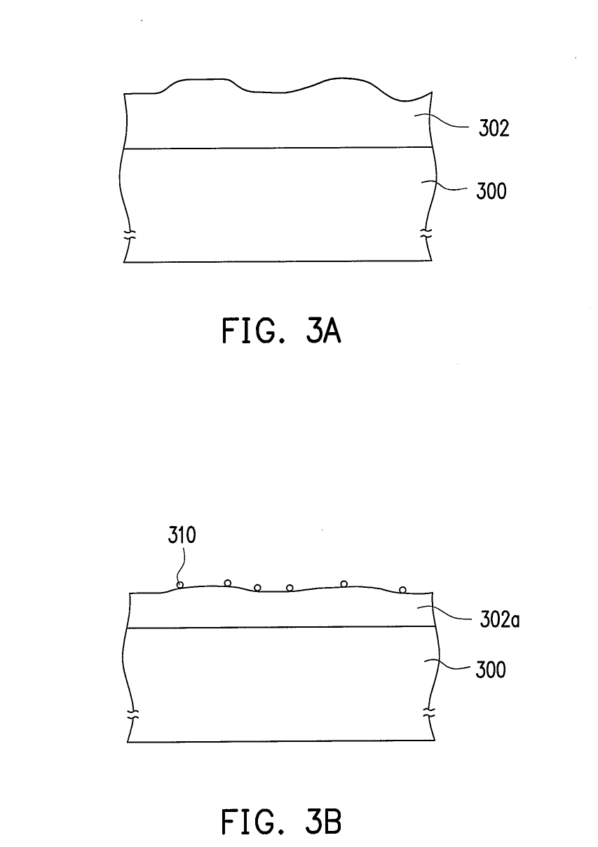

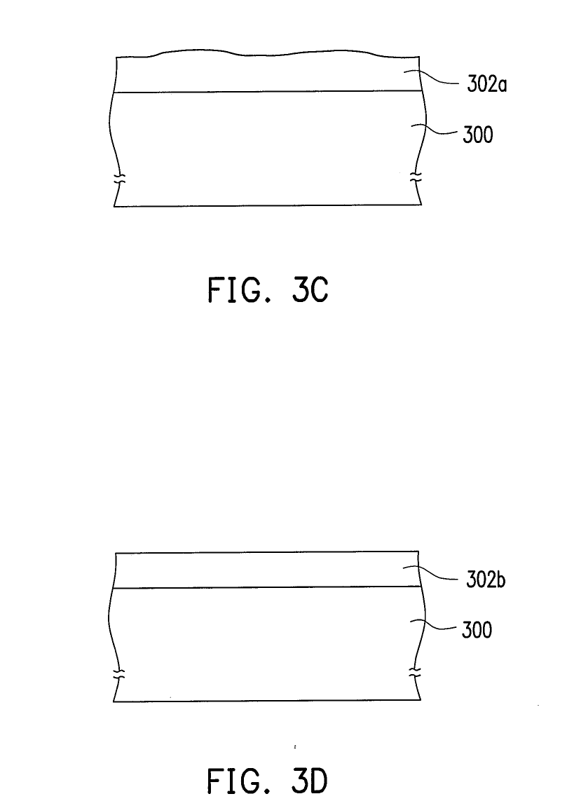

FIGS. 3A-3D depict, in a cross-sectional view, a process flow of the planarization of a dielectric layer of a device according to an embodiment of this invention.

Referring to FIG. 3A, a substrate 300 is provided having a dielectric layer 302 thereon, which may be an inter-layer dielectric (ILD) or inter-metal dielectric (IMD) layer. The dielectric layer 302 has an uneven surface due to the underlying devices, possibly including silicon oxide and possibly formed through CVD.

Referring to FIG. 3B, a non-fixed-abrasive CMP process is conducted (as step 10 in FIG. 1) to remove a part of the dielectric layer 302, such that the remaining dielectric layer 302a has a reduced unevenness. The slurry used in this CMP may be silica-type slurry, such as the SS25 slurry produced by the Cabot Corporation that has a pH value above 7.0. After a non-fixed-abrasive CMP process using silica-type slurry, there are some silica-based abrasive 310 remaining on the surface of the dielectric layer 302a. In an embodiment, the CMP machine used in the planarization includes three polishing platens, wherein the above non-fixed-abrasive CMP is conducted on the first one.

Referring to FIG. 3C, a cleaning step is performed (as step 12 in FIG. 1) to remove the remaining abrasive on the dielectric layer 302a that would otherwise cause undesired particles in next CMP process. When the step 10 utilizes a silica-based abrasive, the substance to be removed is the silica-based abrasive on the dielectric layer 302a. In an embodiment where the CMP machine used in the planarization process includes three polishing platens, the above cleaning step is conducted on the second one. The cleaning step may include flushing of high-pressure DI water and simultaneous buffing, or include application of a chemical solution (with simultaneous buffing).

The chemical solution used may be a base solution, which can change the zeta potential at the surface of the dielectric layer 302a such that the surface of the dielectric layer 302a and the remaining abrasive 310 thereon carry charges of the same sign and repel each other. The base solution may be ammonia, or a solution containing ammonia, such as a solution containing ammonia and H₂O₂ that is possibly an RCA solution produced by the RCA Corporation and containing 20 wt % or less of ammonia.

The chemical solution used may alternatively be an acid-containing solution that removes a portion of the dielectric layer 302a and the remaining abrasive 310 thereon. The acid-containing solution may be dilute hydrofluoric acid or a solution containing hydrofluoric acid in a concentration of 0.02-1 wt %.

Referring to FIG. 3D, a fixed-abrasive CMP process is conducted (as step 14 in FIG. 1) to the dielectric layer 302a to further planarize the dielectric layer 302a into a smoother dielectric layer 302b, wherein the polishing slurry used has a pH value that exceeds 7.0 and is substantially the same as the pH value of the polishing slurry used in the previous non-fixed-abrasive CMP process. In an embodiment where the CMP machine used in the planarization process includes three polishing platens, the above fixed-abrasive CMP process is conducted on the third one. The fixed-abrasive CMP process may use a polishing pad embedded with a ceria-based abrasive therein. For the above step 12 had removed the remaining silica-based abrasive used in the first CMP process, the microscratch caused by CeₓSiO_{y} particles can be effectively reduced

Moreover, a buffing step with DI water flushing may be further conducted (as step 16 in FIG. 1) as required, so as to remove the residues on the dielectric layer 302b.

Though each of the above embodiments includes a non-fixed-abrasive CMP process and a subsequent fixed-abrasive CMP process, this invention is also applicable to a case where a fixed-abrasive CMP process is conducted before a non-fixed-abrasive one, both CMP processes are non-fixed-abrasive CMP processes, both CMP processes are fixed-abrasive CMP processes or two CMP processes of other type(s) are performed, and where the two CMP processes use two different kinds of slurry of which the two kinds of abrasives can interact with each other to form undesired particles.

Moreover, though in the above embodiments the substance capable of causing undesired particles in the second CMP process is the remains of the abrasive used in the first CMP process, this invention is also applicable to the cases where the substance capable of causing undesired particles in the second CMP process is a substance other than the abrasive that is used or produced in the first CMP process, if only the above cleaning step is adjusted as required.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of removing an insulating layer on a substrate, comprising a first CMP process and a second CMP process performed in sequence, wherein
a polishing slurry used in the first CMP process and a polishing slurry used in the second CMP process have substantially the same pH value that exceeds 7.0, and
a cleaning step is conducted between the first and the second CMP processes to remove a specific substance which would otherwise cause undesired particles in the second CMP process.

2. The method of claim 1, wherein the cleaning step is conducted on a polishing platen that is the same as or different from a polishing platen used in the first CMP process.

3. The method of claim 1, wherein the first CMP process comprises a non-fixed-abrasive CMP process and the second CMP process comprises a fixed-abrasive CMP process.

4. The method of claim 3, wherein the specific substance is a first abrasive used in the first CMP process, and the first abrasive can interact with a second abrasive used in the second CMP process to form the undesired particles.

5. The method of claim 4, wherein the first abrasive includes silicon oxide, the second abrasive includes cerium oxide and the undesired particles include CeₓSiO_{y}.

6. The method of claim 4, wherein the cleaning step includes flushing the substrate with deionized water and simultaneously buffing the substrate.

7. The method of claim 6, wherein the cleaning step is conducted on a polishing platen that is the same as or different from a polishing platen used in the first CMP process.

8. The method of claim 7, wherein the cleaning step is conducted on a polishing platen equipped with a buff pad that is different from the polishing platen used in the first CMP process.

9. The method of claim 4, wherein the cleaning step comprises:
treating the substrate with a chemical solution such that a surface of the insulating layer and the first abrasive remaining thereon have charges of the same sign; and
simultaneously buffing the substrate.

10. The method of claim 9, wherein the cleaning step is conducted on a polishing platen different from a polishing platen used in the first CMP process.

11. The method of claim 10, wherein the cleaning step is conducted on a polishing platen equipped with a buff pad.

12. The method of claim 9, wherein the chemical solution comprises ammonia or a solution containing ammonia.

13. The method of claim 4, wherein the cleaning step comprises using a chemical solution to remove a portion of the insulating layer and the first abrasive remaining thereon.

14. The method of claim 13, wherein the cleaning step is conducted in a chemical solution tank.

15. The method of claim 13, wherein the cleaning step further comprises simultaneously buffing the substrate.

16. The method of claim 15, wherein the cleaning step is conducted on a polishing platen different from a polishing platen used in the first CMP process.

17. The method of claim 16, wherein the cleaning step is conducted on a polishing platen equipped with a buff pad.

18. The method of claim 13, wherein the chemical solution comprises an acid solution.

19. The method of claim 18, wherein the acid solution comprises dilute hydrofluoric acid or a solution containing hydrofluoric acid.

20. The method of claim 3, wherein the non-fixed-abrasive CMP process, the fixed-abrasive CMP process and the cleaning step are conducted in one CMP machine.

21. The method of claim 1, wherein the first and the second CMP processes each independently comprise a non-fixed-abrasive CMP process or a fixed-abrasive CMP process.

22. The method of claim 1, wherein the insulating layer is for forming an insulator of a shallow trench isolation (STI) structure.

23. The method of claim 1, wherein the insulating layer is a dielectric layer.

24. The method of claim 1, further comprising, after the second CMP process is performed, a step of flushing the substrate with deionized water and simultaneously buffing the substrate to remove residues on the substrate.

25. A chemical mechanical polishing (CMP) process for polishing a target layer on a substrate, comprising:
conducting a first CMP step to the target layer on a first polishing platen;
conducting, after the first CMP step, a cleaning step to the target layer on a second polishing platen; and
conducting, after the cleaning step, a second CMP step to the target layer on a third polishing platen,
wherein the cleaning step removes a specific substance which would otherwise cause undesired particles in the second CMP process, and
a polishing slurry used in the first polishing platen and a polishing slurry used in the third polishing platen have substantially the same pH value that exceeds 7.0.

26. The CMP process of claim 25, wherein the second polishing platen is equipped with a buff pad.

27. The CMP process of claim 26, wherein the cleaning step includes flushing the substrate with deionized water and simultaneously buffing the substrate.

28. The CMP process of claim 26, wherein the cleaning step includes treating the substrate with a chemical solution and simultaneously buffing the target layer.

29. The CMP process of claim 28, wherein the chemical solution comprises ammonia or a solution containing ammonia.

30. The CMP process of claim 28, wherein the chemical solution comprises an acid solution.

31. The CMP process of claim 30, wherein the acid solution comprises dilute hydrofluoric acid or a solution containing hydrofluoric acid.

32. The CMP process of claim 26, wherein the first and the second CMP steps each independently comprise a non-fixed-abrasive CMP step or a fixed-abrasive CMP step.

33. The CMP process of claim 26, wherein the first CMP step uses a first abrasive that includes silicon oxide, the second CMP step uses a second abrasive that includes cerium oxide, and the undesired particles include CeₓSiO_{y}.
